(19) United States
(12) Patent Application Publication
(10) Pub. No.: US 2006/0250079 A1
(43) Pub. Date: Nov. 9, 2006

(54) INTERMEDIATE LAYERS TREATED BY CF4-PLASMA FOR STACKED ORGANIC LIGHT-EMITTING DEVICES

(75) Inventors: Hoi Sing KWOK, Hong Kong (CN); Man WONG, Hong Kong (CN); Jiaxin SUN, Hong Kong (CN); Xiuling ZHU, Hong Kong (CN); Huajun PENG, Hong Kong (CN)

Correspondence Address: HESLIN ROTHENBERG FARLEY & MESITI PC, 5 COLUMBIA CIRCLE, ALBANY, NY, 12203, US

(73) Assignee: The Hong Kong University of Science and Technology, Hong Kong SAR (CN)

(21) Appl. No.: 11/278,729

(22) Filed: Apr. 5, 2006

Related U.S. Application Data
(60) Provisional application No. 60/668,142, filed on Apr. 5, 2005.

(51) Int. Cl. H01L 51/52; H05B 33/00

(52) U.S. Cl. 313/506; 313/504; 428/690; 428/917; 257/96; 257/E51.018

(57) ABSTRACT

There is disclosed a structure for a stacked organic light emitting device in which a plurality of emissive units are disposed between the anode and the cathode. The emissive units comprise at least a hole-transport layer and an electron-transport layer. An intermediate layer is disposed between two adjacent emissive units and the intermediate layer comprises at least two sub-layers, a first sub-layer being formed of a material that can inject electrons into one emissive unit and a second sub-layer being formed of a material that can inject holes into the adjacent emissive unit. The sub-layers are formed of metals or inorganic materials only and a surface of the intermediate layer may be treated by a low pressure CF₄-plasma.

### CROSS REFERENCE TO RELATED APPLICATIONS

This application claims priority from U.S. Provisional Application No. 60/668,142 filed Apr. 5, 2005, the entire disclosure of which is incorporated herein by reference.

### FIELD OF THE INVENTION

This invention relates to organic light emitting diodes (OLEDs). In particular, the invention relates to a structure for a stacked OLED and provides methods of fabricating such structures.

### BACKGROUND OF THE INVENTION

Since Tang & van Slyke introduced the first ultra-thin and low-voltage organic light emitting diode, much development has been carried out to improve this device for application in flat panel displays (FPDs) as well as in lighting applications. Research on how to improve the device emission efficiency continues to be the focus of this field. In general, this can be achieved through the use of highly efficient luminescent materials and in designing novel device structures. Common to such devices is a basic emissive structure of a layer of an organic light emitting material sandwiched between a hole transporting layer and an electron transporting layer. Such emissive units are placed between an anode and cathode layers to form the basic device structure.

Kido et al, fabricated a multiphoton device consisting of stacked units of OLEDs. In this device multiple units of OLEDs are connected in series where the OLEDs are deposited as thin films onto the same substrate. In such a device, the same current flows through all the OLEDs so that the light output is multiplied. The current efficiency is therefore increased. The crux of such a stacked device is the use of an inter-OLED electrode charge generation layer, which can act as both an anode to one OLED device and as a cathode to the adjacent OLED device. Conductive materials such as ITO or insulating materials such as V₂O₅ or F₄-TCNQ have been used. Liao et al, also introduced another kind of highly efficient tandem OLED, in which the connecting unit was made of organic materials consisting of a combination of Alq₃:Li/NPB:FeCl₃ or TPBi:Li/NPB:FeCl₃. Both of these devices showed very high luminous efficiency.

A number of other designs for stacked OLED structures are known.

U.S. Pat. No. 5,703,436 discloses a multicolor organic light emitting device that employs vertically stacked layers of double heterostructure devices, which are fabricated from organic compounds. The vertical stacked structure is formed on a glass base having a transparent coating of ITO or similar metal to provide a substrate. Deposited on the substrate is the vertical stacked arrangement of three double heterostructure devices, each fabricated from a suitable organic material. Stacking is implemented such that the double heterostructure with the longest wavelength is on the top of the stack. This constitutes the device emitting red light on the top with the device having the shortest wavelength, namely, the device emitting blue light, on the bottom of the stack. Located between the red and blue device structures is the green device structure. The devices are configured as stacked to provide a staircase profile whereby each device is separated from the other by a thin transparent conductive contact layer to enable light emanating from each of the devices to pass through the semitransparent contacts and through the lower device structures while further enabling each of the devices to receive a selective bias. The devices are substantially transparent when de-energized, making them useful for heads-up display applications.

U.S. Pat. No. 5,757,139 discloses arrangements for biasing the individual light emitting elements of a stacked organic light emitting device (SOLED). A circuit is provided for independently driving the individual OLEDs in a conventional SOLED having one electrode coupled to ground potential and one further electrode for each of the OLEDs in the stack. Additionally, new SOLED structures are described in which each OLED in the stack is provided with a ground reference. A SOLED combining upright and inverted OLEDs is also described.

U.S. Pat. No. 6,166,489 describes light emitting devices including at least one pixel comprising a first light emitting stack and a second light emitting stack placed side-by-side. The first and second light emitting stacks each comprise a first OLED and a second OLED over the first OLED. The first light emitting stack further includes a down-conversion layer under the first OLED. Together, the first and second stacks are capable of emitting any visible color of light.

U.S. Pat. No. 6,232,714 discloses the use of optical cavities in a stacked organic light emitting device (SOLEDs) that can shift or attenuate the light emitted by the individual organic light emitting devices (OLEDs) in the stack. Interference caused by reflections within the stack, absorption, positioning of the light source, and the polarization of the emitted light can all determine how the spectra of the emitted light are affected by the SOLED structure. A detailed model that provides a good fit to measured SOLED emissions can be used to predict how a SOLED will affect light emitted by OLEDs. As a result, SOLED geometries that will optimize color saturation and external quantum efficiency can be predicted.

In U.S. Pat. No. 6,274,980 an organic light emitting device (OLED) which emits high intensity light is formed as a stack of individual OLEDs simultaneously emitting light of the same color.

U.S. Pat. No. 6,337,492 discloses a light emitting device that comprises a plurality of stacked organic light emitting devices. The plurality of organic light emitting devices are arranged in a stack. The light emitting device further includes a controller for controlling operation of each of the plurality of organic light emitting devices in the stack. The controller supplies the same current to each of the organic light emitting devices in the stack. The controller simultaneously supplies the same current to each of the plurality of the organic light emitting devices.

### SUMMARY OF THE INVENTION

According to the present invention there is provided a stacked organic light emitting device comprising: (a) an anode; (b) a cathode; (c) a plurality of emissive units disposed between the anode and the cathode, wherein the emissive units comprise at least a hole-transport layer and an electron-transport layer; and (d) an intermediate layer disposed between two adjacent said emissive units, wherein the intermediate layer consists of at least two sub-layers, a first sub-layer being formed of a material that can inject electrons into one emissive unit and a second sub-layer being formed of a material that can inject holes into the adjacent emissive unit.

Preferably a surface of the intermediate layer may be treated by a low pressure CF₄-plasma.

Possible structures for the intermediate layer include films of LiF/Ca/Ag or Li/Al/Au which may be deposited sequentially by thermal evaporation.

More generally, a first material comprising the intermediate layer may comprise a metallic material having a work function lower than 3.0 eV so as to effectively match that of an adjacent electron-transport layer, and a second material comprising the intermediate layer may comprise a metallic material having a work function higher than 4.0 eV so as to effectively match that of an adjacent hole-transport layer.

Preferably the intermediate layer further comprises a sub-layer of an inorganic isolative material (eg LiF or CsF) to enhance electron injection. The intermediate layer may also comprise a sub-layer of an inorganic isolative material (eg V₂O₅) to enhance the ability of hole injection. Where provided the layers of inorganic isolative material may have a thickness in a range of 1 nm to 5 nm.

The sub-layers forming the intermediate layer may have a thickness in a range of 10 nm to 50 nm, and the intermediate layer is at least semi-transparent.

### BRIEF DESCRIPTION OF THE DRAWINGS

Some embodiments of the invention will now be described by way of example and with reference to the accompanying drawings, in which:

FIG. 1 is a schematic cross-section of an OLED according to an embodiment of the invention,

FIG. 2 shows the luminous efficiency characteristics of Example 1 and Example 2,

FIG. 3 shows the luminous efficiency characteristics of Example 3 and Example 4,

FIG. 4 shows the luminous efficiency characteristics of Example 5,

FIG. 5 shows the luminous efficiency characteristics of Example 6,

FIG. 6 shows the luminous efficiency characteristics of Example 7 and Example 8, and

FIG. 7 shows the luminous efficiency characteristics of Example 9.

### DETAILED DESCRIPTION OF PREFERRED EMBODIMENTS

The present invention, at least in its preferred forms, provides an inter-OLED electrode layer consisting of LiF/Ca/Ag or LiF/Al/Au formed in sequence by thermal evaporation in a vacuum chamber to connect the adjacent emissive units in stacked OLEDs. The surface of the silver or gold sub-layer may be treated with CF₄-plasma to enhance the ability of carrier injection, especially hole injection, into the emissive unit.

The luminous efficiency of the fabricated stacked OLEDs utilizing this intermediate layer is significantly improved compared to a conventional OLED consisting of a single emissive unit. The fabricated two-unit stacked device has almost double the luminous efficiency.

Using this intermediate layer to connect the adjacent emissive units, the need for alkali metal doping is removed which means that there is no need for a dispenser or other separate vacuum chamber exclusively for alkali metals. The fabrication process is simple and the process time is efficient because all the films of the stacked OLEDs are prepared by thermal evaporation without breaking vacuum and the CF₄-plasma treatment only lasts for about 10 seconds.

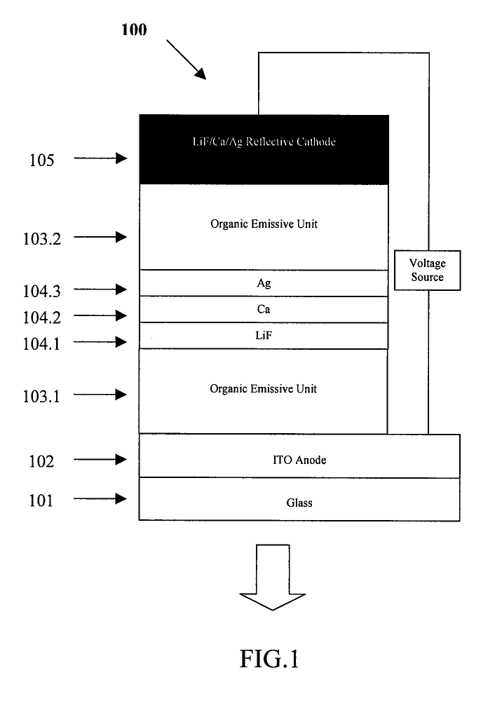

Shown in FIG. 1 is a schematic cross-section of a stacked OLED 100 according to an embodiment of the present invention. The stacked OLED 100 has a ˜75 nm thick indium-tin oxide (ITO) anode 102 coated on glass substrate 101 and a LiF/Ca/Ag reflective cathode 105. Organic emissive units 103.1 and 103.2 are inserted between the anode and cathode with emissive unit 103.1 adjacent the anode layer, and 103.2 adjacent the cathode layer. Disposed between the two organic emissive units 103.1, 103.2 is an intermediate layer 104. Intermediate layer 104 comprises, in sequence, a thin film of LiF 104.1 with a preferred thickness of 1 nm and adjacent emissive unit 103.1, a calcium layer 104.2 with a preferred thickness of 25 nm and a silver layer 104.3 adjacent emissive unit 103.2 and with a preferred thickness of 15 nm (as will be discussed below the surface of silver layer 104.3 is preferably treated by CF₄-plasma).

When an electric potential is applied to the stacked OLED 100, holes are injected from anode 102 into the organic emissive unit 103.1, and electrons are injected from cathode 105 into the organic emissive unit 103.2. At the same time, electrons and holes are generated and separated from the intermediate LiF/Ca/Ag layer 104 (with the silver surface treated by CF₄-plasma) and are injected into the lower emissive unit 103.1 and upper emissive unit 103.2, respectively. In other words, in the intermediate layer LiF/Ca/Ag 104, the LiF/Ca layers 104.1/104.2 can effectively function as a cathode to the lower emissive unit 103.1, while the Ag layer acts as the anode to the upper emissive unit 103.2. Holes and electrons recombine in the two emissive unit regions and light is emitted through the transparent ITO anode and the glass substrate as shown by the arrow in FIG. 1.

The combined structure of the intermediate layer plays a key role in the stacked OLED mentioned above. In addition to the LiF/Ca/Ag sequence described above, the intermediate layer may also consist of, in sequence, a thin film of LiF with a preferred thickness of 1 nm, a calcium layer with the preferred thickness of 3 nm and a gold layer with a preferred thickness of 15 nm. The thin films in the intermediate layer are all prepared by thermal deposition in the same vacuum chamber with the base pressure lower than 10⁻⁶ torr. After film deposition, the silver or gold film surface is preferably treated by CF₄-plasma in a separate vacuum chamber.

More generally still it will be understood that the intermediate layer should comprise two layers of different metals: one metal must be capable of emitting electrons into the emissive layer adjacent the anode (eg LiF in the examples discussed above), while the other metal layer (eg Ag or Au) must be capable of injecting holes into the emissive unit adjacent the cathode. One metal of the intermediate layer should preferably have a work function lower than 3.0 eV so as to effectively match that of an adjacent electron-transport layer, while the other metal of the intermediate layer should have a work function higher than 4.0 eV so as to effectively match that of an adjacent hole-transport layer. The intermediate layer may also include a sub-layer of an inorganic isolative material such as LiF or CsF to enhance electron injection, and may also include a sub-layer of an inorganic isolative material such as V₂O₅ to enhance the hole injection.

The following examples are presented for a further understanding of the present invention. Examples 1, 2, 5, 7 and 8 are examples of conventional structures provided for comparison, Examples 3, 4, 6 and 9 are examples of structures according to embodiments of the invention.

The materials and layers formed therefrom will be abbreviated as follows:
ITO: indium-tin-oxide;
CF₄: Quart-Fluorocarbon gas; used as the working gas in the treatment chamber at 20 Pa;
NPB: 4,4′-N,N′-di(naphthalene-1-yl)-N,N′-diphenyl-benzidine;
Alq₃: tris(8-hydroxyquinoline)aluminium(III);
C545T: 10-(2-benzothiazolyl)-1,1,7,7-tetramethyl-2,3,6,7-tetrahydro-1H,5H,11H-benzo[1]pyrano[6,7,8-ij]quinolizin-11-one;
BCP: 2,9-Dimethyl-4,7-diphenyl-1,10-phenanthroline;
CBP: 4,4′-Bis(carbazol-9-yl)biphenyl;
Ir(ppy)₃: tris(2-phenylpyridine)iridium
LiF/Ca/Ag or LiF/Al/Au: Lithium fluoride/Calcium/Silver or Lithium fluoride/Aluminium/Gold; used for the intermediate layer and/or as the top cathode material.

### EXAMPLES 1 AND 2

Examples 1 and 2 are examples of conventional OLED structures with single emissive units. Approximately 1.1 mm thick glass coated with ITO was cleaned and dried and then used as the starting substrate. The thickness of the ITO layer was about 75 nm with a sheet resistance of about 25Ω/cm². The ITO surface of example 1 and the silver surface of example 2 were both treated by CF₄-plasma at the same time in the same batch and therefore with the same treatment conditions. After this treatment, the substrate was transferred into a vacuum chamber for thin film deposition in the sequence of: NPB(50 nm)/Alq₃:C545T(30 nm, 2% wt)/BCP(20 nm)/LiF(1 nm)/Ca(20 nm)/Ag(80 nm).

Example 1 has a structure of ITO(CF₄-Plasma treated)/NPB(50 nm)/Alq₃:C545T(30 nm, 2% wt)/BCP(20 nm)/LiF(1 nm)/Ca(20 nm)/Ag(80 nm).

Example 2 has a structure of ITO/Ag(15 nm, CF₄-Plasma treated)/NPB(50 nm)/Alq₃ :C545T(30 nm, 2 wt %)/BCP(20 nm)/LiF(1 nm)/Ca(20 nm)/Ag(80 nm).

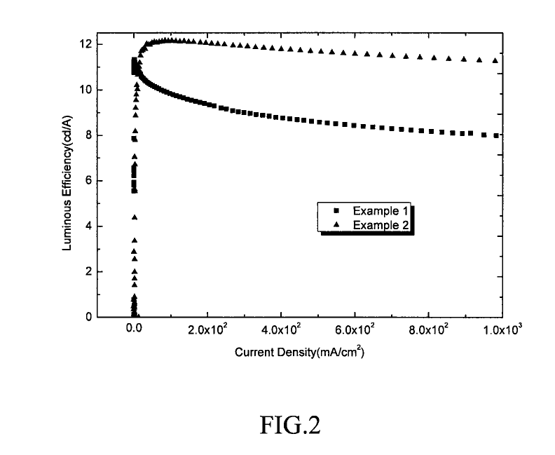

Shown in FIG. 2 is the luminous efficiency versus current density curves of devices made according to Examples 1 and 2. The luminous efficiency of the devices of Examples 1 and 2 is about 10.5 cd/A and 11.6 cd/A respectively under the current density of 20 mA/cm² which requires a driving voltage of 6.1V and 6.3V, respectively.

### EXAMPLES 3 AND 4

Examples 3 and 4 are embodiments of the invention in which stacked OLEDs are formed with intermediate LiF/Ca/Ag layers provided between stacked emissive units. Approximately 1.1 mm thick glass coated with ITO was cleaned and dried and then used as the starting substrate. The thickness of ITO is about 75 nm with a sheet resistance of about 25Ω/cm². The ITO surface of Example 3 and the silver surface of Example 4 were both treated by CF₄-plasma at the same time in the same batch and therefore with the same treatment conditions as mentioned above. After this treatment, the substrate was transferred into a vacuum chamber for thin film deposition in the sequence of NPB(50 nm)/Alq₃:C545T(30 nm, 2% wt)/BCP(20 nm)/LiF(1 nm)/Ca(25 nm)/Ag(15 nm, CF₄-Plasma treated)/NPB(50 nm)/Alq₃:C545T(30 nm, 2% wt)/BCP(20 nm)/LiF(1 nm)/Ca(20 nm)/Ag(80 nm). It should be noted that the silver surface of the intermediate layer (LiF/Ca/Ag in this case) was also treated by CF₄-plasma with the same treatment conditions as those of ITO anode and Ag anode.

Example 3 has a structure of ITO(CF₄-Plasma treated)/NPB(50 nm)/Alq₃:C545T(30 nm, 2% wt)/BCP(20 nm)/LiF(1 nm)/Ca(25 nm)/Ag(15 nm, CF₄-Plasma treated)/NPB(50 nm)/Alq₃:C545T(30 nm, 2% wt)/BCP(20 nm)/LiF(1 nm)/Ca(20 nm)/Ag(80 nm).

In Example 3 there are two emissive units formed by the layers NPB(50 nm)/Alq₃:C545T(30 nm, 2% wt)/BCP(20 nm) separated by the intermediate layer formed by the sequence LiF(1 nm)/Ca(25 nm)/Ag(15 nm, CF₄-Plasma treated). The final three layers LiF(1 nm)/Ca(20 nm)/Ag(80 nm) comprises the cathode.

Example 4 has a structure of ITO/Ag(15 nm, CF₄-Plasma treated)/NPB(50 nm)/Alq₃:C545T(30 nm, 2% wt)/BCP(20 nm)/LiF(1 nm)/Ca(25 nm)/Ag(15 nm, CF₄-Plasma treated)/NPB(50 nm)/Alq₃:C545T(30 nm, 2% wt)/BCP(20 nm)/LiF(1 nm)/Ca(20 nm)/Ag(80 nm).

In Example 4 there are two emissive units formed by the layers NPB(50 nm)/Alq₃:C545T(30 nm, 2% wt)/BCP(20 nm) separated by the intermediate layer LiF(1 nm)/Ca(25 nm)/Ag(15 nm, CF₄-plasma treated). The final sequence of layers LiF(1 nm)/Ca(20 nm)/Ag(80 nm) comprises the cathode.

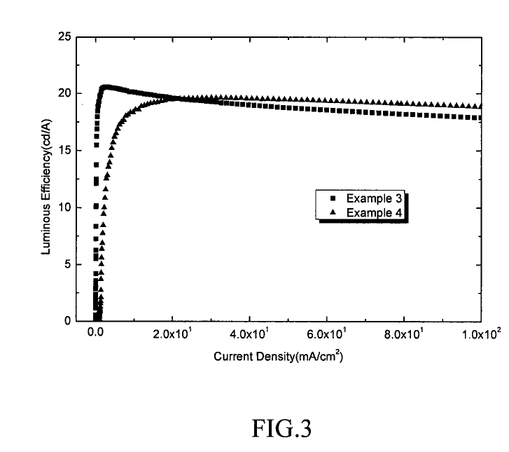

Shown in FIG. 3 is the luminous efficiency versus current density curves of devices according to Examples 3 and 4. The luminous efficiency of the devices of Examples 3 and 4 is about 19.6 cd/A and 19.5 cd/A under the current density of 20 mA/cm² which requires a driving voltage of 10.4V and 10.3V, respectively.

### EXAMPLE 5

Example 5 is an example of a conventional OLED structure with a single NPB(40 nm)/CBP:Ir(ppy)₃(25 nm, 6% wt)/BCP(35 nm) emissive unit and a cathode of LiF(1 nm)/Ca(20 nm)/Ag(80 nm). Approximately 1.1 mm thick glass coated with ITO was cleaned and dried and then used as the starting substrate. The thickness of ITO is about 75 nm with a sheet resistance of about 25Ω/cm². The ITO surface of Example 5 was treated by CF₄-plasma with the same treatment conditions as mentioned above. After this treatment, the substrate was transferred into a vacuum chamber for thin film deposition in the sequence of NPB(40 nm)/CBP:Ir(Ppy)₃(25 nm, 6% wt)/BCP(35 nm)/LiF(1 nm)/Ca(20 nm)/Ag(80 nm).

Example 5 has a structure of ITO(CF₄-plasma treated)/NPB(40 nm)/CBP:Ir(ppy)₃(25 nm, 6% wt)/BCP(35 nm)/LiF(1 nm)/Ca(20 nm)/Ag(80 nm).

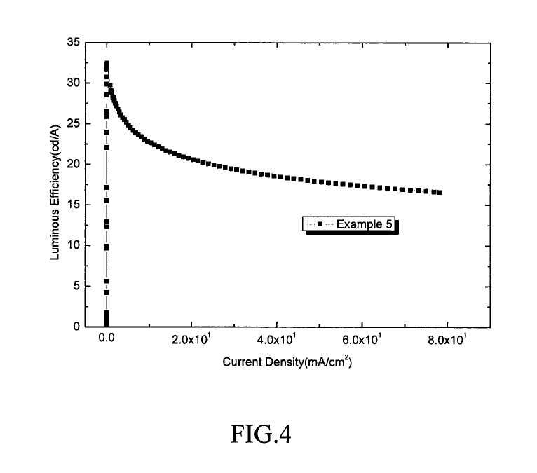

Shown in FIG. 4 is the luminous efficiency versus current density curve for a device according to Example 5. The luminous efficiency of the device of Example 5 is about 29 cd/A under the current density of 1 mA/cm².

### EXAMPLE 6

Example 6 is an embodiment of the invention in which a Li/Ca/Ag intermediate layer is provided between two stacked NPB(40 nm)/CBP:Ir(ppy)₃(25 nm, 6% wt)/BCP(35 nm) emissive units. Approximately 1.1 mm thick glass coated with ITO was cleaned and dried and then used as the starting substrate. The thickness of ITO is about 75 nm and the sheet resistance is about 25Ω/cm². The ITO surface of Example 6 was treated by CF₄-plasma with the same treatment conditions as mentioned above. After this treatment, the substrate was transferred into a vacuum chamber for thin film deposition in the sequence of NPB(40 nm)/CBP:Ir(ppy)₃(25 nm, 6% wt)/BCP(35 nm)/LiF(1 nm)/Ca(25 nm)/Ag(15 nm, CF₄-plasma treated)/NPB(40 nm)/CBP:Ir(ppy)₃(25 nm, 6% wt)/BCP(35 nm)/LiF(1 nm)/Ca(20 nm)/Ag(80 nm). It should be noted that the silver surface of the intermediate layer (LiF/Ca/Ag in this case) was also treated by CF₄-plasma with the same treatment condition as that of ITO anode.

Example 6 has a structure of ITO(CF₄-Plasma treated)/NPB(40 nm)/CBP:Ir(ppy)₃(25 nm, 6% wt)/BCP(35 nm)/LiF(1 nm)/Ca(25 nm)/Ag(15 nm, CF₄-plasma treated)/NPB(40 nm)/CBP:Ir(ppy)₃(25 nm, 6% wt)/BCP(35 nm)/LiF(1 nm)/Ca(20 nm)/Ag(80 nm).

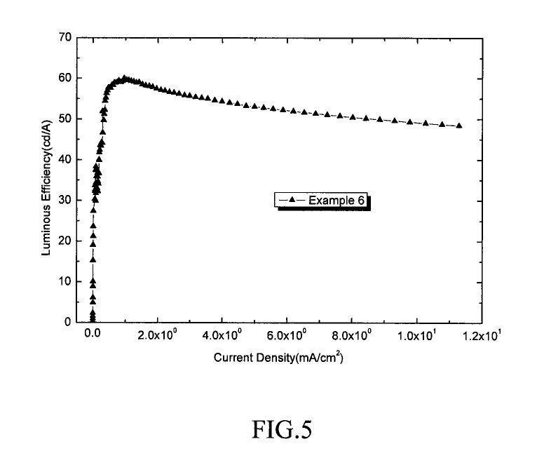

Shown in FIG. 5 is the luminous efficiency versus current density curves of a device according to Example 6. The luminous efficiency of the device according to Example 6 reaches a maximum value of 60 cd/A under the current density of 1 mA/cm².

### EXAMPLE 7 AND 8

Examples 7 and 8 are conventional OLED structures with a single emissive unit of NPB(50 nm)/Alq₃:C545T(30 nm, 2% wt)/BCP(20 nm) and a cathode formed of LiF(1 nm)/Al(3 nm)/Au(15 nm)/Al(120 nm).

Approximately 1.1 mm thick glass coated with ITO was cleaned and dried and then used as the starting substrate. The thickness of ITO is about 75 nm and the sheet resistance is about 25Ω/cm². The ITO surface of example 7 and the gold surface of example 8 were both treated by CF₄-plasma at the same time in the same batch and therefore with the same treatment condition as mentioned above. After this treatment, the substrate was transferred into a vacuum chamber for thin film deposition in the sequence of NPB(50 nm)/Alq₃:C545T(30 nm, 2% wt)/BCP(20 nm)/LiF(1 nm)/Al(3 nm)/Au(15 nm)/Al(120 nm).

Example 7 has a structure of ITO(CF₄-Plasma treated)/NPB(50 nm)/Alq₃:C545T(30 nm, 2 % wt)/BCP(20 nm)/LiF(1 nm)/Al(3 nm)/Au(15 nm)/Al(120 nm).

Example 8 has a structure of ITO/Au(15 nm, CF₄-Plasma treated)/NPB(50 nm)/Alq₃ :C545T(30 nm, 2% wt)/BCP(20 nm)/LiF(1 nm)/Al(3 nm)/Au(15 nm)/Al(120 nm).

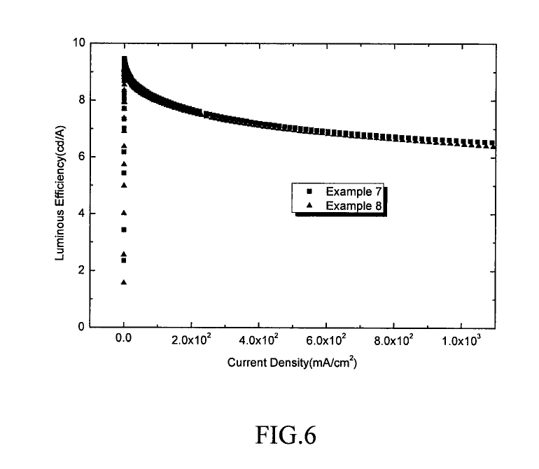

Shown in FIG. 6 is the luminous efficiency versus current density curves of devices formed according to Examples 7 and 8. The luminous efficiency of the devices of Examples 7 and 8 is about 8.8 cd/A and 8.6 cd/A respectively under the current density of 20 mA/cm² which requires a driving voltage of 7V and 6.9V, respectively.

### EXAMPLE 9

Example 9 is an embodiment of the invention in which an intermediate layer of LiF/Al/Au is provided between two stacked NPB(50 nm)/Alq₃:C545T(30 nm, 2% wt)/BCP(20 nm) emissive units.

Approximately 1.1 mm thick glass coated with ITO was cleaned and dried and then used as the starting substrate. The thickness of ITO is about 75 nm and the sheet resistance is about 25Ω/cm². The ITO surface of Example 9 was treated by CF₄-plasma with the same treatment condition as mentioned above. After this treatment, the substrate was transferred into a vacuum chamber for thin film deposition in the sequence of NPB(50 nm)/Alq₃:C545T(30 nm, 2% wt)/BCP(20 nm)/LiF(1 nm)/Al(3 nm)/Au(15 nm, CF₄-Plasma treated)/NPB(50 nm)/Alq₃:C545T(30 nm, 2% wt)/BCP(20 nm)/LiF(1 nm)/Al(150 nm). It may be noted that the gold surface of the intermediate layer (LiF/Al/Au in this Example) was also treated by CF₄-plasma with the same treatment conditions as the ITO anode.

Example 9 has a structure of ITO(CF₄-Plasma treated)/NPB(50 nm)/Alq₃:C545T(30 nm, 2% wt)/BCP(20 nm)/LiF(1 nm)/Al(3 nm)/Au(15 nm, CF₄-Plasma treated)/NPB(50 nm)/Alq₃:C545T(30 nm, 2% wt)/BCP(20 nm)/LiF(1 nm)/Al(150 nm).

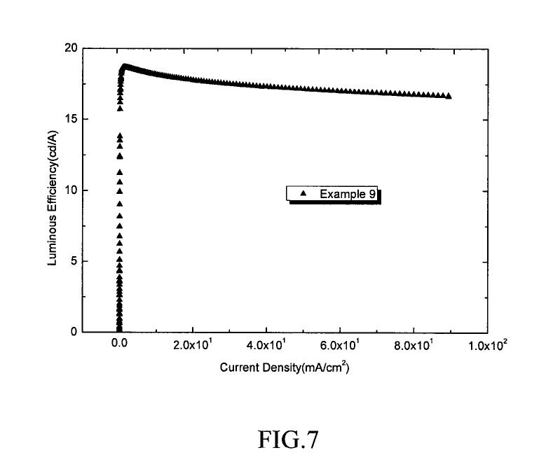

Shown in FIG. 7 is the luminous efficiency versus current density curve of a device according to Example 9. The luminous efficiency of the device of Example 9 is about 17.7 cd/A under the current density of 20 mA/cm² which requires a driving voltage of 15.5V.

It will thus be seen that at least in its preferred forms the present invention teaches the construction of a stacked OLED device where the inter-OLED electrode materials consist of LiF/Ca/Ag or LiF/Al/Au multiple layers all formed in such a sequence by thermal evaporation in a vacuum chamber to connect the adjacent emissive units in stacked OLEDs. Further, there is provided a method of treating the surface of the inter-OLED layer, that is the preferred surface of silver or gold, to improve the carrier (especially hole) injection and therefore the electrical and optical performance of the device fabricated.

The above examples demonstrate that significant improvement or increase in luminous efficiency can be achieved by inserting an intermediate layer between two stacked emissive units. Preferred forms of the intermediate layer are LiF/Ca/Ag or LiF/Al/Au with the top silver or gold surface preferably being treated by CF₄-plasma. More generally, the intermediate layer is chosen such that it comprises one sub-layer of a material capable of emitting electrons into one emissive unit, and another sub-layer of a material capable of emitting holes into the other emissive unit. Notably the intermediate layers are formed of metallic and/or inorganic materials only, no organic materials are used, which makes them easier to deposit by thermal evaporation processes.

By means of the present invention it is possible to increase light output utilizing the same current as a single conventional OLEDS or to achieve the same light output with less current. The invention has been described in detail with certain preferred embodiments thereof, but it will be understood and the variations and modifications can be effected within the scope of the invention.

1. A stacked organic light emitting device comprising:
(a) an anode;
(b) a cathode;
(c) a plurality of emissive units disposed between the anode and the cathode, wherein the emissive units comprise at least a hole-transport layer and an electron-transport layer; and
(d) an intermediate layer disposed between two adjacent said emissive units, wherein the intermediate layer consists of at least two sub-layers, a first sub-layer being formed of a material that can inject electrons into one emissive unit and a second sub-layer being formed of a material that can inject holes into the adjacent emissive unit, wherein a surface of said intermediate layer has been treated by a low pressure CF₄-plasma.

2. A device as claimed in claim 1 wherein the intermediate layer comprises films of LiF/Ca/Ag deposited sequentially by thermal evaporation.

3. A device as claimed in claim 1 wherein the intermediate layer comprises films of LiF/Al/Au deposited sequentially by thermal evaporation.

4. A device as claimed in claim 1 wherein a first said material comprising the intermediate layer comprises a metallic material having a work function lower than 3.0 eV so as to effectively match that of an adjacent electron-transport layer.

5. A device as claimed in claim 1 wherein a second said material comprising the intermediate layer comprises a metallic material having a work function higher than 4.0 eV so as to effectively match that of an adjacent hole-transport layer.

6. A device as claimed in claim 1 wherein the intermediate layer further comprises a sub-layer of an inorganic isolative material to enhance electron injection.

7. A device as claimed in claim 1 wherein said inorganic isolative material comprises LiF or CsF.

8. A device as claimed in claim 1 wherein the intermediate layer further comprises a sub-layer of an inorganic isolative material to enhance the ability of hole injection.

9. A device as claimed in claim 8 wherein said inorganic isolative material comprises V₂O₅.

10. A device as claimed in claim 1 wherein the sub-layers forming the intermediate layer have a thickness in a range of 10 nm to 50 nm.

11. A device as claimed in claim 10 wherein the intermediate layer is at least semi-transparent.

12. A device as claimed in claim 6 wherein said layers of isolative inorganic materials have a thickness in a range of 1 nm to 5 nm.

13. A device as claimed in claim 8 wherein said layers of isolative inorganic materials have a thickness in a range of 1 nm to 5 nm.

14. A stacked organic light emitting device comprising:
an anode;
a cathode;
a plurality of emissive units disposed between the anode and the cathode, wherein the emissive units comprise at least a hole-transport layer and an electron-transport layer; and
an intermediate layer disposed between two adjacent said emissive units, wherein the intermediate layer consists of at least two sub-layers, a first sub-layer being formed of a material that can inject electrons into one emissive unit and a second sub-layer being formed of a material that can inject holes into the adjacent emissive unit, wherein said intermediate layers are formed of metals and/or inorganic materials only.

15. A stacked organic light emitting device comprising:
an anode; a cathode; a plurality of emissive units disposed between the anode and the cathode, wherein the emissive units comprise at least a hole-transport layer and an electron-transport layer; and an intermediate layer disposed between two adjacent said emissive units, wherein the intermediate layer consists of at least two sub-layers, a first sub-layer being formed of a material that can inject electrons into one emissive unit and a second sub-layer being formed of a material that can inject holes into the adjacent emissive unit.
